(19) United States
(12) Patent Application Publication
(10) Pub. No.: US 2008/0121883 A1
(43) Pub. Date: May 29, 2008

(54) SEMICONDUCTOR DEVICE AND MANUFACTURING METHOD THEREOF

(75) Inventor: Young Suk KIM, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU LIMITED, Kawasaki-shi (JP)

(21) Appl. No.: 11/961,317

(22) Filed: Dec. 20, 2007

Related U.S. Application Data
(63) Continuation of application No. PCT/JP2005/012595, filed on Jul. 7, 2005.

(51) Int. Cl. H01L 29/12; H01L 21/336

(52) U.S. Cl. 257/51; 438/285; 257/E29.255; 257/E21.409

(57) ABSTRACT

A disclosed semiconductor device includes a gate electrode that is arranged on a substrate via a gate dielectric film. A gate electrode head is formed on the gate electrode, which gate electrode head is wider than the gate electrode, and extends between a first side wall dielectric film and a second side wall dielectric film that are formed on the same sides as first and second sides of the gate electrode, respectively. A first diffusion region is formed in the substrate on the same side as the first side of the gate electrode and a second diffusion region is formed in the substrate on the same side as the second side of the gate electrode. The gate electrode includes polysilicon at least at a bottom part in contact with the gate dielectric film.

### CROSS-REFERENCE TO RELATED APPLICATION

This application is a U.S. continuation application filed under 35 USC 111(a) claiming benefit under 35 USC 120 and 365(c) of PCT application JP2005/012595, filed Jul. 7, 2005. The foregoing application is hereby incorporated herein by reference.

### BACKGROUND OF THE INVENTION

1. Field of the Invention

The present invention generally relates to semiconductor devices. More particularly, the present invention relates to an ultra-microscopic, ultra-high-speed semiconductor device having a gate length of less than 40 nm, and a manufacturing method thereof.

2. Description of the Related Art

Generally, in a MOS transistor, in order to reduce the contact resistance, a low-resistance silicide layer made of CoSi₂, NiSi, or the like, is formed on the silicon surfaces of the source area, the drain area, the gate electrode, etc., by a salicide method or the like.

In a salicide method, a metal film such as a Co film or a Ni film is deposited on the surfaces of the source area, a drain area, and a gate electrode, and the metal film is then heat-treated so that a desired silicide layer is formed on the silicon surfaces. Unreacted portions of the metal layer are removed by a wet etching process (see, for example, Patent Document 1).

Patent Document 1: Japanese Laid-Open Patent Application No. H7-202184

Non-patent Literature 1: Bin Yu et al., International Electronic Device Meeting Tech. Dig., 2001, pp. 937

Non-patent Literature 2: N. Yasutake, et al., 2004 Symposium on VLSI Technology Digest of Technical Papers, pp. 84

Recently, due to the progress of ultra-microscopic technology, semiconductor devices having a gate length of less than 100 nm have been put into practice. Research is being conducted on so-called ultra-microscopic/ultra-high-speed semiconductor devices having 65 nm nodes, 45 nm nodes, or 32 nm nodes.

In such ultra-microscopic semiconductor devices, the gate length is also reduced to under 40 nm, for example, to 15 nm or 6 nm (see, Non-patent Literature 1 and 2). However, in such semiconductor devices with extremely short gate lengths, it is difficult to form silicide layers. Accordingly, a problem arises in that the gate resistance increases.

FIGS. 1A through 1C are diagrams for describing the problem that arises when forming a silicide layer, by the conventional salicide method, in such an ultra-microscopic/ultra-high-speed semiconductor device. In the following description, a p-channel MOS transistor is taken as an example; the same description is applicable to an n-channel MOS transistor by inverting the conductivity type.

As shown in FIG. 1A, on a silicon substrate 11, a device area 11A including an n-type well is defined by device separation areas 11I having an STI structure. In the device area 11A, there is formed a p+ type polysilicon gate electrode 13 corresponding to a predetermined channel area on the silicon substrate 11 via a gate dielectric film 12.

In the portion of the silicon substrate 11 corresponding to the device area 11A, a p-type source extension area 11a and a p-type drain extension area 11b are formed on opposite sides of the polysilicon gate electrode 13. On each side wall of the polysilicon gate electrode 13, a side wall oxide film 130W made of a CVD oxide film is formed in such a manner that each side wall oxide film 130W continuously extends to cover part of the source extension area 11a or the drain extension area 11b of the silicon substrate 11.

The side wall oxide film 130W is provided for the purpose of blocking a current path of a gate leakage current along the side wall surface of the polysilicon gate electrode 13. On each side wall oxide film 130W is formed a side wall dielectric film 13SW made of a material having high HF resistance, such as SiN or SiON.

In the portion of the silicon substrate 11 corresponding to the device area 11A, a p+ type source area 11c and a p+ type drain area 11d are formed in such a manner as to be on the outside of each of the side wall dielectric films 13SW.

In the step shown in FIG. 1B, a metal film 14 made of Co, Ni, or the like, is deposited on the structure shown in FIG. 1A by a sputtering method or the like. In the step shown in FIG. 1C, heat-treatment is performed to cause the metal film 14 to react with the silicon surface underneath. Accordingly, a low-resistance silicide layer 15 made of CoSi2, NiSi, or the like, is formed on the surfaces of the source area 11c, the drain area 11d, and on the surface of the polysilicon gate electrode 13. Furthermore, unreacted portions of the metal film 14 are removed by a wet etching process. Consequently, a device structure as shown in FIG. 1C is formed.

However, in such a device structure, if the gate length of the gate electrode 13 is reduced to under 40 nm, for example, to 15 nm or 6 nm, the proportion of the silicide layer 15 formed on the polysilicon gate electrode 13 will become extremely small. Hence, even if the silicide layer 15 is formed, the sheet resistance will increase. Therefore, it will not be possible to reduce the gate resistance to a desired level. Accordingly, the semiconductor device will not be able to realize a desired operational speed.

In order to solve these problems, Patent Document 1 proposes a configuration for reducing the sheet resistance of the polysilicon gate electrode by forming a wide gate electrode head at the tip of the polysilicon gate electrode having a short gate length, and forming a silicide layer on the gate electrode head.

FIGS. 2A and 2B are diagrams for describing the steps for manufacturing a semiconductor device disclosed in Patent Document 1.

As shown in FIG. 2A, on top of a silicon substrate 21, a device area is defined by device separation areas 22a, 22b, 24a, and 24b. On top of the device area is formed a silicon layer 23 acting as a channel layer, in an epitaxial manner. On the device separation areas 24a and 24b, the silicon layer 23 is in a polycrystal state, i.e., polysilicon.

FIG. 2A further illustrates a polysilicon gate electrode 25 formed on the silicon layer 23 via a gate dielectric film 24, corresponding to a channel area in the silicon layer 23. Side wall dielectric films are formed around the polysilicon gate electrode 25 in such a manner that the top of the polysilicon gate electrode 25 is exposed. On this structure, an SiGe layer is deposited, so that SiGe layers 27a and 27c are formed on the left and the right of the polysilicon gate electrode 25 and a SiGe polycrystal head 27b is formed as a wide head on the exposed top part of the polysilicon gate electrode 25.

In the step shown in FIG. 2B, a metal film made of Co, Ni, or the like, is deposited on the structure shown in FIG. 2A, and a salicide process is performed so that the SiGe layers 27a through 27c are converted into silicide areas 28a through 28c. On the polysilicon gate electrode 25 is formed the silicide area 28b, having a broad width and low resistance, as the gate electric head.

As described above, according to the technology disclosed in Patent Document 1, a wide polycrystal area is formed on a gate electrode having a short gate length, and the polycrystal area is converted into silicide. Accordingly, a wide head having sufficiently low sheet resistance can be formed on the top of the gate electrode in the form of a silicide layer. However, the inventor of the present invention has found that in such a device stricture, if the gate length is reduced to under 40 nm, or further reduced to 15 nm or 6 nm, the gate leakage current will increase.

FIG. 3 is an SEM image of a structure in which a polycrystal head was actually formed on a polysilicon gate electrode. It can be observed that the polycrystal head is covering part of the surfaces of the side wall dielectric films on opposite sides of the gate electrode.

For this reason, in this structure, the distance between the wide gate electrode head 28b and the silicide area 28a or the silicide area 28b will be reduced. Accordingly, as indicated by arrows in FIG. 2B, gate leakage current paths will be formed along the surfaces of the side wall dielectric films. As described above, the side wall dielectric films are SiN or SiON films that generally have HF resistance. These films generally have high interface densities on their surfaces, and therefore, a leakage current path will be easily formed via the surfaces with high interface densities.

### SUMMARY OF THE INVENTION

The present invention provides a semiconductor device and a manufacturing method thereof in which one or more of the above-described disadvantages are eliminated.

An embodiment of the present invention provides a semiconductor device including a substrate; a gate electrode arranged on the substrate via a gate dielectric film, wherein a first side of the gate electrode is defined by a first side wall and a second side of the gate electrode is defined by a second side wall, the second side wall being opposite to the first side wall; and the gate electrode comprises a first width; a first side wall dielectric film formed on the substrate on the same side as the first side of the gate electrode, the first side wall dielectric film including a first inner wall opposite to and spaced apart from the first side wall; a second side wall dielectric film formed on the substrate on the same side as the second side of the gate electrode, the second side wall dielectric film including a second inner wall opposite to and spaced apart from the second side wall; a gate electrode head formed on the gate electrode in such a manner as to extend from the first inner wall and the second inner wall, wherein the gate electrode head comprises a second width that is greater than the first width; and a first extension area formed in the substrate on the same side as the first side of the gate electrode and a second extension area formed in the substrate on the same side as the second side of the gate electrode, wherein the gate electrode head is formed in such a manner as to contact the gate electrode; and the gate electrode comprises polysilicon at least at a bottom part of the gate electrode in contact with the gate dielectric film.

An embodiment of the present invention provides a method of manufacturing a semiconductor device, which method includes the steps of forming a polysilicon gate electrode defined by a first side wall and a second side wall on a substrate via a gate dielectric film; forming a first extension area in the substrate on the same side as the first side wall of the polysilicon gate electrode and a second extension area in the substrate on the same side as the second side wall of the polysilicon gate electrode; forming a first side wall oxide film on the first side wall on a first side of the polysilicon gate electrode and a second side wall oxide film on the second side wall on a second side of the polysilicon gate electrode; forming, on the first side wall oxide film, a first side wall dielectric film having a different etching resistance from that of the first side wall oxide film, and forming, on the second side wall oxide film, a second side wall dielectric film having a different etching resistance from that of the second side wall oxide film; etching the first side wall oxide film and the second side wall oxide film, starting from top edges thereof, selectively and partially with respect to the first side wall dielectric film and the second side wall dielectric film, in such a manner as to expose the first side wall and the second side wall at a top part of the polysilicon gate electrode; filling, with a polycrystal silicon material, a gap between the exposed first side wall and the first side wall dielectric film and a gap between the exposed second side wall and the second side wall dielectric film, to thereby form a gate electrode head extending between an inner wall of the first side wall dielectric film and an inner wall of the second side wall dielectric film; and forming a silicide layer on the gate electrode head.

An embodiment of the present invention provides a method of manufacturing a semiconductor device, which method includes the steps of forming a polysilicon gate electrode defined by a first side wall and a second side wall on a substrate via a gate dielectric film; forming a first extension area in the substrate on the same side as the first side wall of the polysilicon gate electrode and a second extension area in the substrate on the same side as the second side wall of the polysilicon gate electrode; forming a first side wall oxide film on the first side wall on a first side of the polysilicon gate electrode and a second side wall oxide film on the second side wall on a second side of the polysilicon gate electrode; forming, on the first side wall oxide film, a first side wall dielectric film having a different etching resistance from that of the first side wall oxide film, and forming, on the second side wall oxide film, a second side wall dielectric film having a different etching resistance from that of the second side wall oxide film; etching the first side wall oxide film and the second side wall oxide film, starting from top edges thereof, selectively and partially with respect to the first side wall dielectric film and the second side wall dielectric film, in such a manner as to expose a top part of the polysilicon gate electrode; etching the exposed polysilicon gate electrode in such a manner as to form a first gap in the polysilicon gate electrode between the first side wall oxide film and the second side wall oxide film, wherein the first gap is in communication with a second gap formed between the first side wall dielectric film and the second side wall dielectric film; filling the first gap and the second gap with a polycrystal silicon material to thereby form a gate electrode head extending between an inner wall of the first side wall dielectric film and an inner wall of the second side wall dielectric film; and forming a silicide layer on the gate electrode head.

According to one embodiment of the present invention, a gate electrode head with a broad width can be formed on a polysilicon gate electrode, which width corresponds to a length between a first side wall dielectric film and a second side wall dielectric film. By forming a low-resistance silicide layer on the gate electrode head by a salicide process, a low gate resistance is ensured and a semiconductor device can operate at ultra-high speed, even if a gate length is reduced to under 40 nm, for example, to around 15 nm or 6 nm, or even less.

### BRIEF DESCRIPTION OF THE DRAWINGS

Other objects, features and advantages of the present invention will become more apparent from the following detailed description when read in conjunction with the accompanying drawings, in which:

FIG. 1A illustrates a conventional salicide process;

FIG. 1B illustrates a conventional salicide process;

FIG. 1C illustrates a conventional salicide process;

FIG. 2A illustrates a problem of the conventional technology;

FIG. 2B illustrates a problem of the conventional technology;

FIG. 3 illustrates a problem of the conventional technology;

FIG. 4A illustrates a method of manufacturing a semiconductor device according to a first embodiment (part 1);

FIG. 4B illustrates a method of manufacturing a semiconductor device according to the first embodiment (part 2);

FIG. 4C illustrates a method of manufacturing a semiconductor device according to the first embodiment (part 3);

FIG. 4D illustrates a method of manufacturing a semiconductor device according to the first embodiment (part 4);

FIG. 4E illustrates a method of manufacturing a semiconductor device according to the first embodiment (part 5);

FIG. 4F illustrates a method of manufacturing a semiconductor device according to the first embodiment (part 6);

FIG. 4G illustrates a method of manufacturing a semiconductor device according to the first embodiment (part 7);

FIG. 5A illustrates a method of manufacturing a semiconductor device according to a second embodiment (part 1);

FIG. 5B illustrates a method of manufacturing a semiconductor device according to the second embodiment (part 2);

FIG. 5C illustrates a method of manufacturing a semiconductor device according to the second embodiment (part 3);

FIG. 5D illustrates a method of manufacturing a semiconductor device according to the second embodiment (part 4);

FIG. 6A illustrates a method of manufacturing a semiconductor device according to a third embodiment (part 1);

FIG. 6B illustrates a method of manufacturing a semiconductor device according to the third embodiment (part 2);

FIG. 6C illustrates a method of manufacturing a semiconductor device according to the third embodiment (part 3); and

FIG. 6D illustrates a method of manufacturing a semiconductor device according to the third embodiment (part 4).

### DETAILED DESCRIPTION OF THE PREFERRED EMBODIMENTS

A description is given, with reference to the accompanying drawings, of an embodiment of the present invention.

### First Embodiment

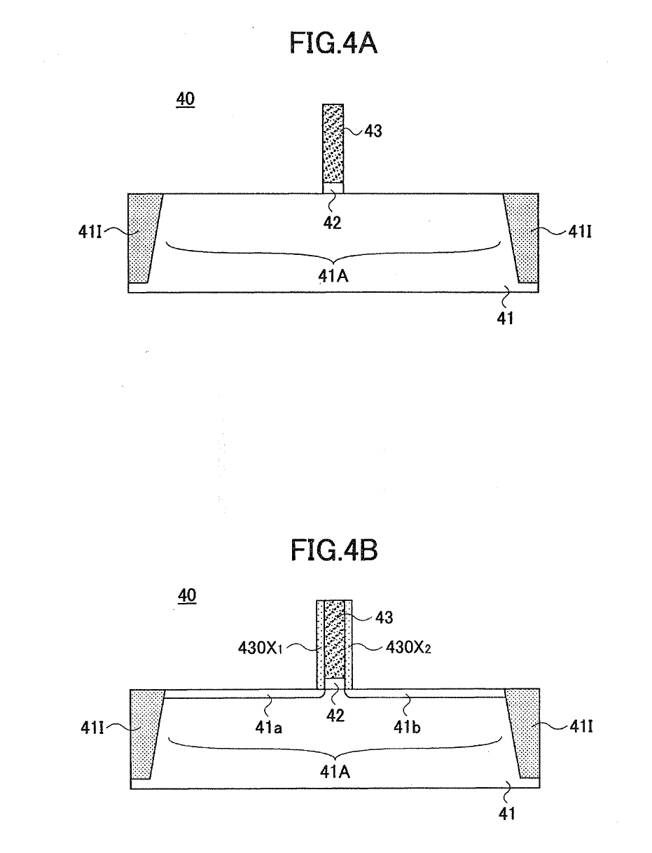

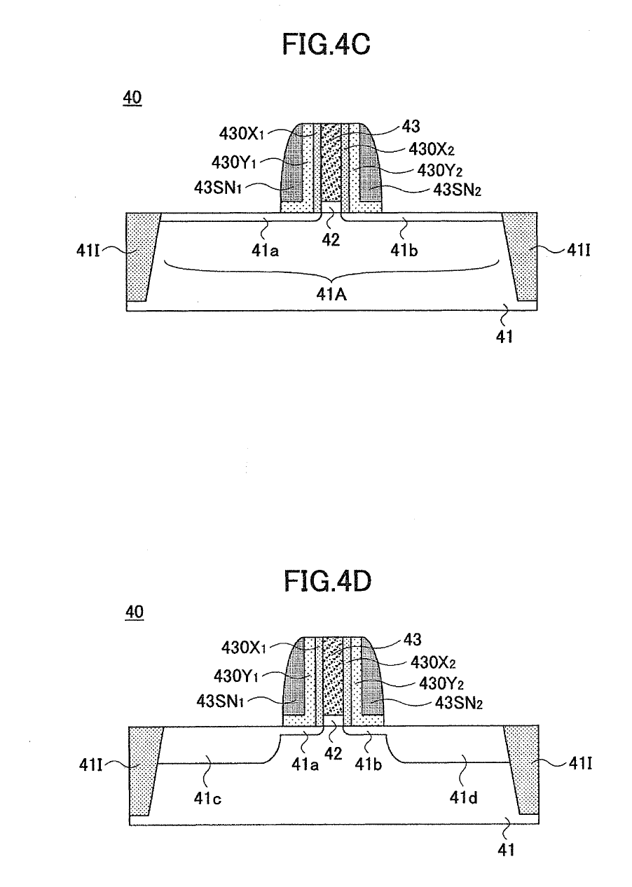

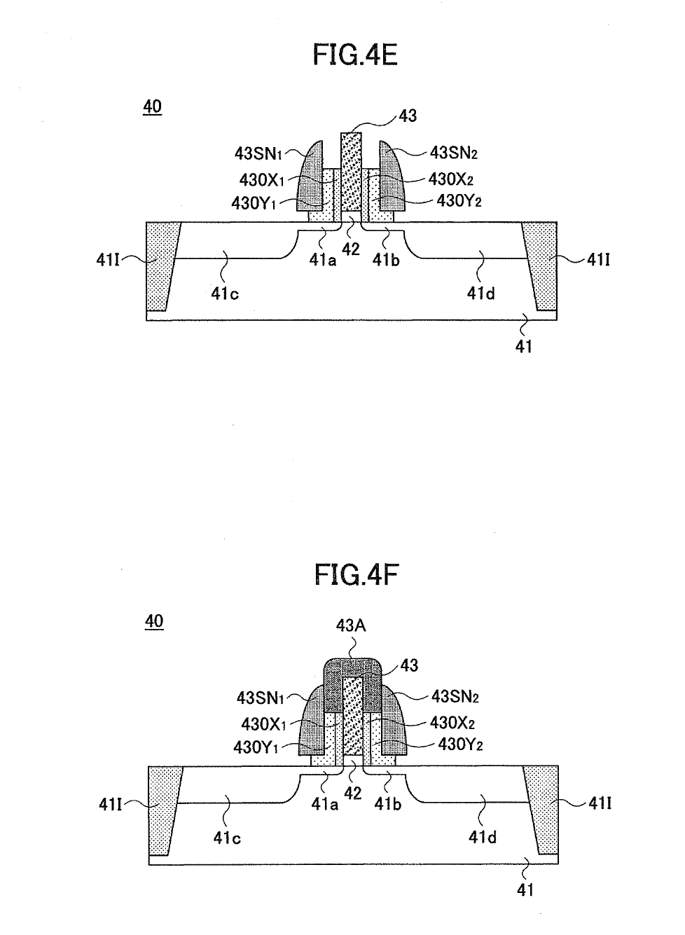

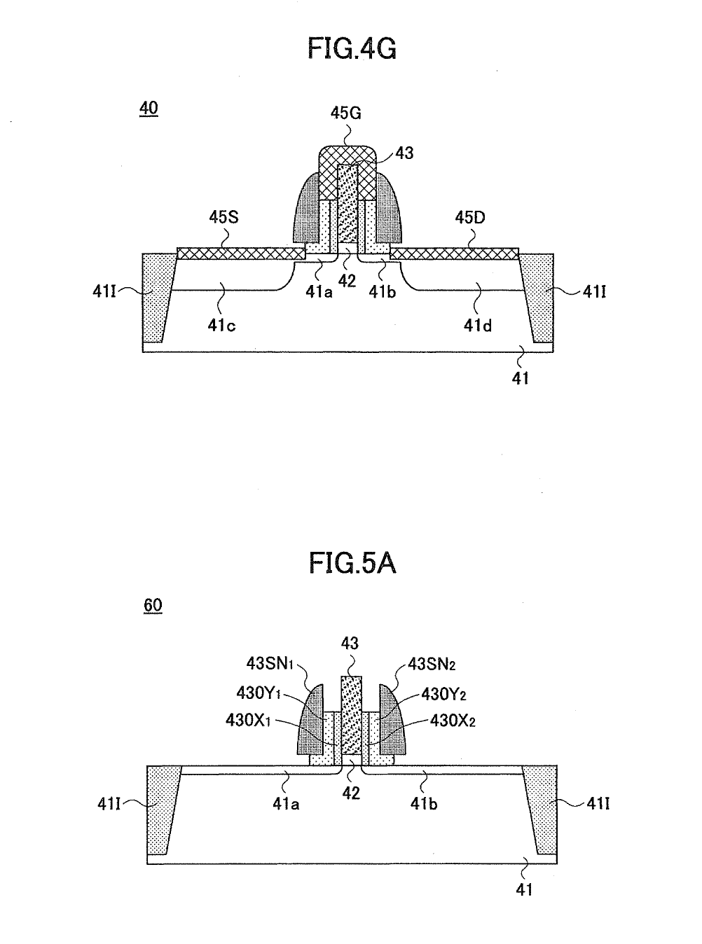

FIGS. 4A through 4G illustrate a method of manufacturing a semiconductor device 40 according to a first embodiment of the present invention. In the following description, a p-channel MOS transistor is taken as an example of the semiconductor device 40; the same description is applicable to an n-channel MOS transistor by inverting the conductivity type.

As shown in FIG. 4A, on a silicon substrate 41, a device area 41A including an n-type well is defined by STI type device separation areas 41I. In the device area 41A, there is formed a polysilicon gate electrode 43 on the silicon substrate 41 via a gate dielectric film 42.

Next, in the step shown in FIG. 4B, a p-type impurity element such as B⁺ is injected into the silicon substrate 41 by ion implantation, with the polysilicon gate electrode 43 acting as a mask. On opposite sides of the polysilicon gate electrode 43, a p-type source extension area 41a and a p-type drain extension area 41b are formed.

In the step shown in FIG. 4B, on opposite sides of the polysilicon gate electrode 43, side wall oxide films 430X₁ and 430X₂ are formed by a CVD method, with each having a thickness of 5 nm through 10 nm. In the step shown in FIG. 4C, outer side wall oxide films 430Y₁ and 430Y₂ are respectively formed on the side wall oxide films 430X₁ and 430X₂ by a CVD method. Each of the outer side wall oxide films 430Y₁ and 430Y₂ continuously extend to cover part of the surface of the silicon substrate 41. Furthermore, in the step shown in FIG. 4C, SiN side wall dielectric films 43SN₁ and 43SN₂ are respectively formed on the outer side wall oxide films 430Y₁ and 430Y₂. The SiN side wall dielectric films 43SN₁ and 43SN₂ formed in this manner have higher HF etching resistance than that of the side wall oxide films 430X₁, 430X₂, 430Y₁, and 430Y₂.

In the step shown in FIG. 4D, a large dose of a p-type impurity element such as B⁺ is injected into the silicon substrate 41 by ion implantation, with the polysilicon gate electrode 43, the side wall oxide films 430X₁, 430X₂, 430Y₁, and 430Y₂, and the side wall dielectric films 43SN₁ and 43SN₂ acting as a mask. Accordingly, a p+ type source extension area 41c and a p+ type drain extension area 41d are formed in the silicon substrate 41 at areas outside the side wall dielectric films 43SN₁ and 43SN₂.

In the step shown in FIG. 4E, the structure shown in FIG. 4D is placed in HF, and wet etching is performed on the side wall dielectric films 43SN₁ and 43SN₂ and the gate electrode 43, so that the side wall oxide films 430X₁, 430X₂, 430Y₁, and 430Y₂ recede. Accordingly, a gap is formed around the gate electrode 43 in such a manner that the top part of the gate electrode 43 is exposed. At this stage, the side wall oxide films between the side wall dielectric film 43SN₁ or 43SN₂ and the silicon substrate 41, i.e., the side wall oxide films 430Y₁ and 430Y₂ are also subjected to wet etching. However, the exposed area of the side wall oxide films 430Y₁ and 430Y₂ is extremely small as shown in FIG. 4D, and therefore, the etching speed is slow. The wet etching of the oxide films primarily occurs along the side wall faces of the gate electrode 43.

In the step shown in FIG. 4F, a polysilicon film is deposited on the structure shown in FIG. 4E, so that the above-described gap is filled. Accordingly, a polysilicon gate electrode head 43A, formed on the gate electrode 43, has a width equal to the distance between the inner wall face of the side wall dielectric film 43SN₁ and the inner wall face of the side wall dielectric film 43SN₂.

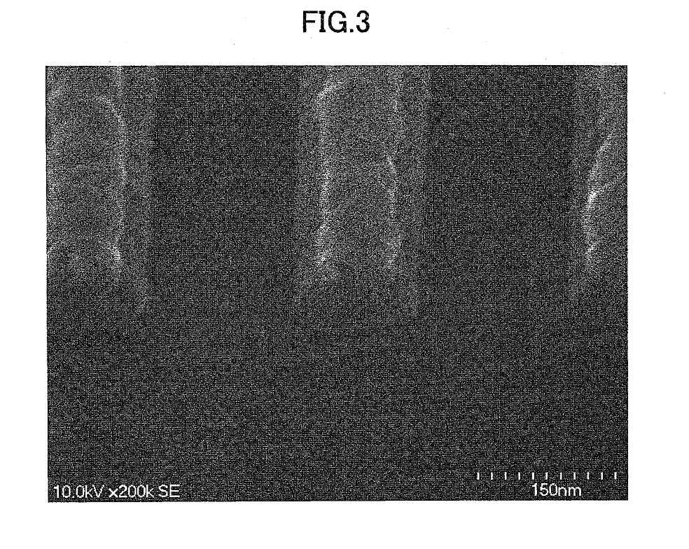

In the example shown in FIG. 4F, the polysilicon gate electrode head 43A is extending above the top ends of the side wall dielectric films 43SN₁ and 43SN₂. However, unlike the case shown in FIG. 3, the width of the polysilicon gate electrode head 43A is substantially the same at the portion between the side wall dielectric films 43SN₁ and 43SN₂ and at the portion extending above the top ends of the side wall dielectric films 43SN₁ and 43SN₂.

In the step shown in FIG. 4F, the source/drain extension areas 41c, 41d are doped to a high impurity concentration. Therefore, if a process for depositing a silicon film is performed to form the above-described polysilicon gate electrode head 43A, a polysilicon film may grow on the source extension area 41c and the drain extension area 41d, but a Si epitaxial layer will not grow on these areas. Furthermore, by optimizing the process of depositing a silicon film, it is possible to mitigate the growth of a polysilicon film. By employing such optimal conditions, it is possible to only form a polysilicon gate electrode head 43A.

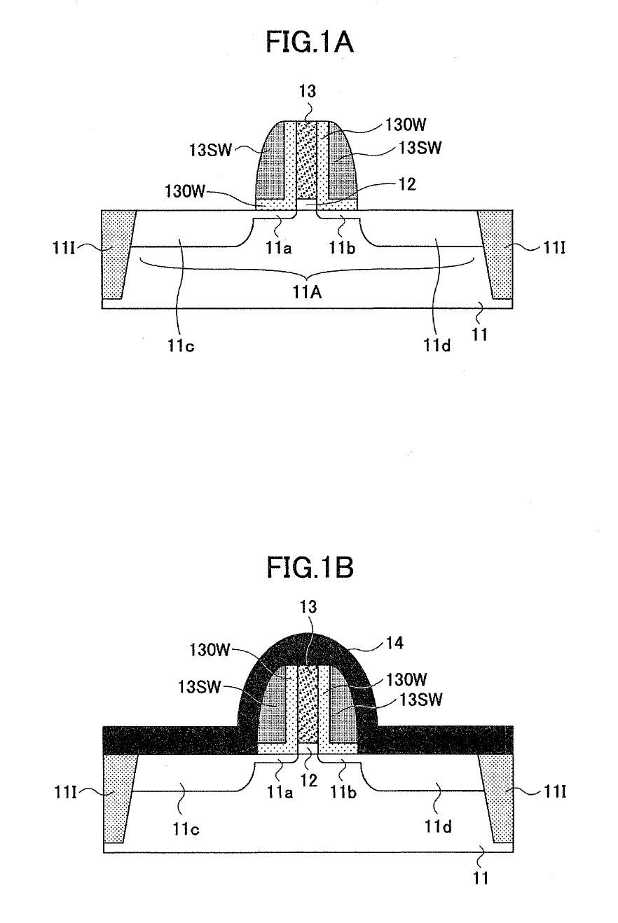

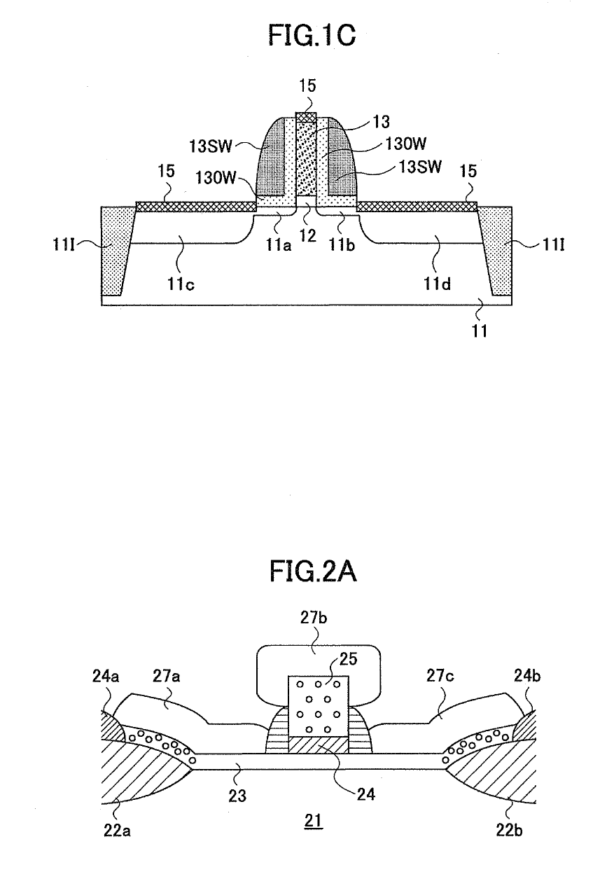

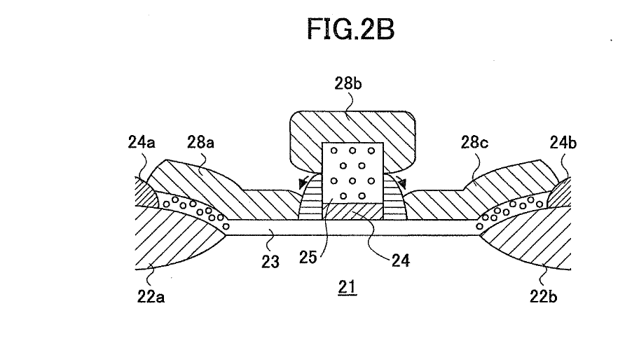

After the wide polysilicon gate electrode head 43A is formed as described above, the salicide steps described with reference to FIGS. 1A through 1C are performed on the structure processed as above. Accordingly, as shown in FIG. 4G, a silicide layer 45G with low sheet resistance is formed on the polysilicon gate electrode head 43A, so that the gate resistance is significantly reduced. At the same time, silicide layers 45S, 45D similar to the silicide layer 45G are formed on the source extension area 41c and the drain extension area 41d, respectively.

Particularly, in the present embodiment, as the side wall oxide films 430X₁ and 430X₂ are formed on the inside of the side wall oxide films 430Y₁ and 430Y₂, the width of the polysilicon gate electrode head 43A is effectively increased.

As mentioned above, in the above description, a p-channel MOS transistor is taken as an example; an embodiment of the present invention is also applicable to an n-channel MOS transistor by replacing the p-type impurity with an n-type impurity in the above description. As the n-type impurity, “As” and “P” are usually employed.

### Second Embodiment

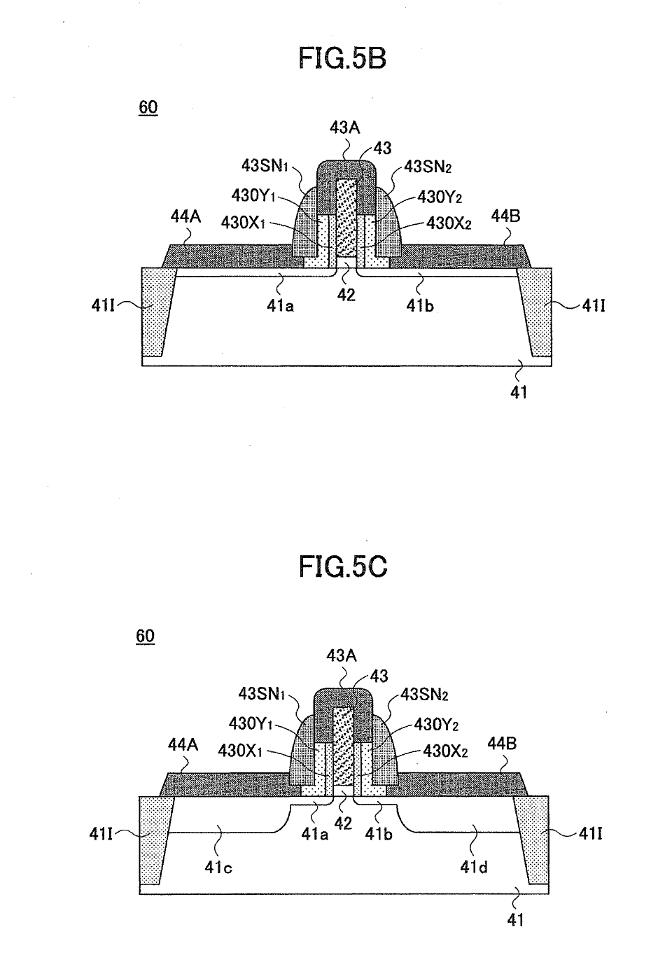

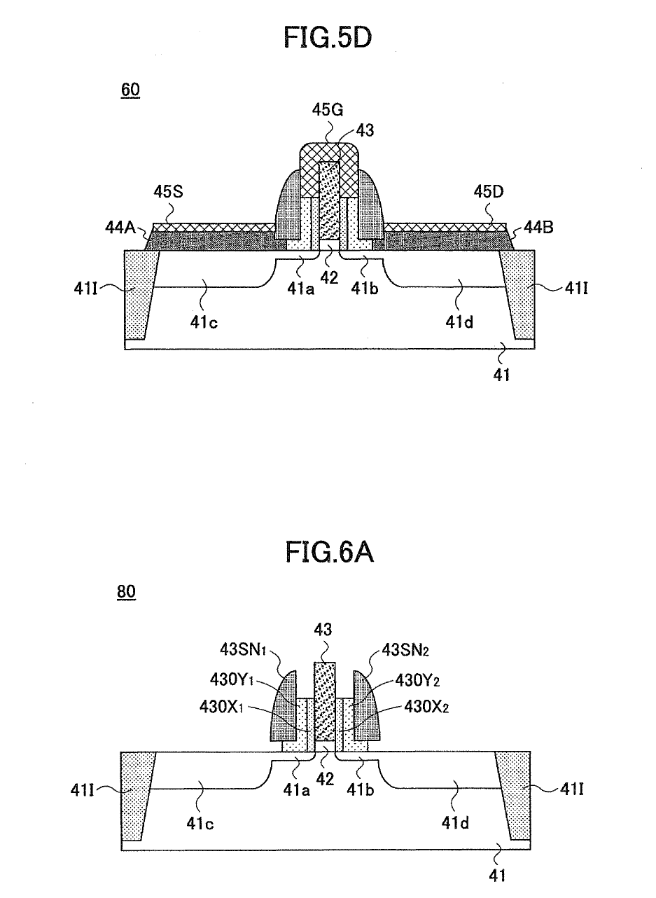

FIGS. 5A through 5D illustrate a method of manufacturing a semiconductor device 60 according to a second embodiment of the present invention. In FIGS. 5A through 5D, elements corresponding to those described above are denoted by the same reference numbers, and are not further described.

In the present embodiment, first, the steps shown in FIGS. 4A through 4C are performed. Then, immediately after these steps, a HF wet etching process is performed on the structure shown in FIG. 4C, so that a structure shown in FIG. 5A is formed, which is similar to the structure shown in FIG. 4E. However, unlike the step shown in FIG. 4D performed after the step shown in FIG. 4C, as shown in FIG. 5A, the source/drain extension areas 41c, 41d, doped to a high concentration, are not yet formed.

In the step shown in FIG. 5B, in the present embodiment, a polysilicon film is deposited on the structure shown in FIG. 5A, similar to the step shown in FIG. 4F. Accordingly, the polysilicon gate electrode head 43A is formed on the gate electrode 43. Furthermore, because the source/drain extension areas 41c, 41d are not yet formed on the surface of the silicon substrate 41, epitaxial growth of silicon layers 44A, 44B occur on the silicon substrate 41 at areas outside of the side wall dielectric films 43SN₁ and 43SN₂.

A large dose of a p-type impurity element such as B⁺ is injected into the structure shown in FIG. 5B formed as above by ion implantation. Accordingly, the p+ type source extension area 41c and the p+ type drain extension area 41d are formed in the silicon substrate 41 at areas outside of the side wall dielectric films 43SN₁, 43SN₂. At the same time, the polysilicon gate electrode head 43A and the gate electrode 43 are doped to be p+ types.

In the structure shown in FIG. 5C, the Si layers 44A, 44B are formed in an epitaxial manner on the silicon substrate 41 as part of the source/drain areas, and therefore, the depth of the extension areas 41c, 41d formed in the silicon substrate 41 as source/drain areas can be reduced by a corresponding amount. As a result, it is possible to reduce leakage currents occurring between the bottom edge of the source extension area and the bottom edge of the drain extension area in the silicon substrate.

Then, in the step shown in FIG. 5D, the above-described salicide process is performed on the structure shown in FIG. 5C. Accordingly, a structure is obtained in which the silicide layer 45G corresponding to the gate electrode head 43A is formed, and silicide layers 45S, 45D are formed in such a manner as to lay upon the source/drain extension areas 41c, 41d, respectively.

### Third Embodiment

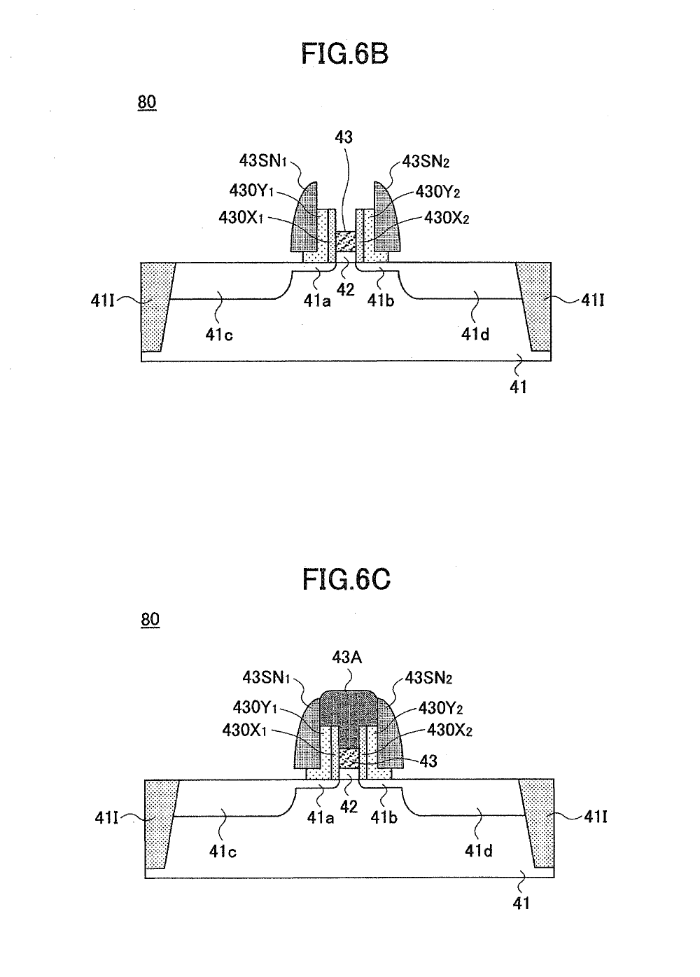

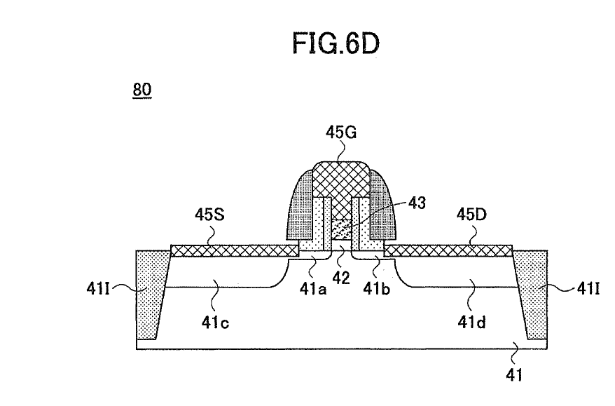

FIGS. 6A through 6D illustrate a method of manufacturing a semiconductor device 80 according to a third embodiment of the present invention. In FIGS. 6A through 6D, elements corresponding to those described above are denoted by the same reference numbers, and are not further described.

The step shown in FIG. 6A corresponds to the step shown in FIG. 4E. A selective wet etching process is performed by using HF to make the side wall oxide films 430X₁, 430Y₁, 430X₂, and 430Y₂ recede, and the top part of the polysilicon gate electrode 43 is exposed.

In the present embodiment, in the step shown in FIG. 6B, the exposed part of the polysilicon gate electrode 43 is made to recede by performing a dry etching process using, for example, HCl as the etchant. The polysilicon gate electrode 43 is made to recede to form a gap defined by the inner wall faces of the side wall oxide films 430X₁ and 430X₂, in such a manner as to be in communication with the gap formed between the inner wall faces of the side wall dielectric films 43SN₁ and 43SN₂.

In the step shown in FIG. 6C, by filling the gap with a silicon polycrystal material such as polysilicon or polycrystal SiGe, a gate electrode top part and head 43 is formed in such a manner as to continue from the polysilicon gate electrode 43. The silicon polycrystal material is deposited by performing a low pressure CVD method using silane (SiH₄) gas or silane gas and germane (GeH₄) gas as the raw material at a substrate temperature of approximately 500° C. Particularly, by forming the gate electrode head 43A with polycrystal SiGe, resistance of the gate electrode head 43A can be reduced even further.

The silicon polycrystal material can be deposited without dopant gas added, and later on an impurity element can be injected by ion implantation; however, the silicon polycrystal material can be deposited with dopant gas added. In this case, the thickness of the polysilicon gate electrode 43 in contact with the gate dielectric film 42 is sufficiently reduced without exposing the gate dielectric film 42. By doing so, the entire gate electrode including the polysilicon gate electrode head 43A can be substantially doped to the desired conductivity type.

Particularly, when the gap is filled with polycrystal SiGe, the semiconductor device is preferably a p-channel MOS transistor.

Furthermore, in the step shown in FIG. 6D, by performing the salicide process described above on the structure shown in FIG. 6C, the silicide layer 45G corresponding to the polysilicon gate electrode head 43A is formed, and the silicide layers 45S, 45D are formed in such a manner as to lay upon the source/drain extension areas 41c, 41d, respectively.

In the present embodiment, similar to the second embodiment, it is also possible to cause the silicon epitaxial layers 44A, 44B to grow on the source/drain extension areas 41c, 41d.

The present invention is not limited to the specifically disclosed embodiment, and variations and modifications may be made without departing from the scope of the present invention.

What is claimed is:

1. A semiconductor device comprising:
a substrate;
a gate electrode arranged on the substrate via a gate dielectric film, wherein a first side of the gate electrode is defined by a first side wall and a second side of the gate electrode is defined by a second side wall, the second side wall being opposite to the first side wall, and the gate electrode comprises a first width;
a first side wall dielectric film formed on the substrate on the same side as the first side of the gate electrode, the first side wall dielectric film comprising a first inner wall opposite to and spaced apart from the first side wall;
a second side wall dielectric film formed on the substrate on the same side as the second side of the gate electrode, the second side wall dielectric film comprising a second inner wall opposite to and spaced apart from the second side wall;
a gate electrode head formed on the gate electrode in such a manner as to extend between the first inner wall and the second inner wall, wherein the gate electrode head comprises a second width that is greater than the first width; and
a first diffusion region formed in the substrate on the same side as the first side of the gate electrode and a second diffusion region formed in the substrate on the same side as the second side of the gate electrode, wherein:
the gate electrode head is formed in such a manner as to contact the gate electrode; and
the gate electrode comprises polysilicon at least at a bottom part of the gate electrode in contact with the gate dielectric film.

2. The semiconductor device according to claim 1, wherein:
the gate electrode head comprises the polysilicon, and silicide is formed on at least a top part of the gate electrode head.

3. The semiconductor device according to claim 1, wherein:
the gate electrode comprises said bottom part, and a top part that contacts the gate electrode head; and
the bottom part and the top part have different compositions.

4. The semiconductor device according to claim 3, wherein:
the top part of the gate electrode comprises SiGe polycrystal; and
the gate electrode head comprises Ge.

5. The semiconductor device according to claim 1, wherein:
the gate electrode head extends above beyond the top ends of the first side wall dielectric film and the second side wall dielectric film with respect to the substrate; and
a part of the gate electrode head located above the top ends of the first side wall dielectric film and the second side wall dielectric film has substantially the same width as that of a part of the gate electrode head located in between the first side wall dielectric film and the second side wall dielectric film.

6. The semiconductor device according to claim 1, wherein:
underneath the gate electrode head, a gap is formed between the first side wall and the first inner wall, and another gap is formed between the second side wall and the second inner wall; and
the gaps are respectively filled with a first oxide film and a second oxide film.

7. The semiconductor device according to claim 6, wherein:
the first oxide film extends into a space between the first side wall dielectric film and a surface of the silicon substrate;
the second oxide film extends into a space between the second side wall dielectric film and the surface of the silicon substrate;
the first oxide film has a thickness that is greater between the first inner wall and the first side wall than between the first side wall dielectric film and the surface of the silicon substrate; and
the second oxide film has a thickness that is greater between the second inner wall and the second side wall than between the second side wall dielectric film and the surface of the silicon substrate.

8. A method of manufacturing a semiconductor device, the method comprising the steps of:
forming a polysilicon gate electrode defined by a first side wall and a second side wall on a substrate via a gate dielectric film;
forming a first diffusion region in the substrate on the same side as the first side wall of the polysilicon gate electrode and a second diffusion region in the substrate on the same side as the second side wall of the polysilicon gate electrode;
forming a first side wall oxide film on the first side wall on a first side of the polysilicon gate electrode and a second side wall oxide film on the second side wall on a second side of the polysilicon gate electrode;
forming, on the first side wall oxide film, a first side wall dielectric film having a different etching resistance from that of the first side wall oxide film, and forming, on the second side wall oxide film, a second side wall dielectric film having a different etching resistance from that of the second side wall oxide film;
etching the first side wall oxide film and the second side wall oxide film, starting from top edges thereof, selectively and partially with respect to the first side wall dielectric film and the second side wall dielectric film, in such a manner as to expose the first side wall and the second side wall at a top part of the polysilicon gate electrode;
filling, with a polycrystal silicon material, a gap between the exposed first side wall and the first side wall dielectric film and a gap between the exposed second side wall and the second side wall dielectric film, to thereby form a gate electrode head in such a manner that it extends between an inner wall of the first side wall dielectric film and an inner wall of the second side wall dielectric film; and
forming a silicide layer on the gate electrode head.

9. The method according to claim 8, further comprising the step of:
forming, in the silicon substrate, a third diffusion region and a fourth diffusion region, outside of the first side wall dielectric film and outside of the second side wall dielectric film, respectively, wherein the third diffusion region and the fourth diffusion region have higher impurity concentrations than those of the first diffusion region and the second diffusion region, wherein:
the step of filling the gaps with the polycrystal silicon material is performed after forming the third diffusion region and the fourth diffusion region.

10. The method according to claim 9, wherein:
the third diffusion region and the fourth diffusion region are doped to have impurity concentration levels at which the polycrystal silicon material does not become deposited at the step of filling the gaps with the polycrystal silicon material.

11. The method according to claim 8, wherein:
the gaps are filled with the polycrystal silicon material in such a manner that a first epitaxial layer and a second epitaxial layer are formed on the silicon substrate, outside of the first side wall dielectric film and outside of the second side wall dielectric film, respectively; and
after the first epitaxial layer and the second epitaxial layer are formed, a third diffusion region and a fourth diffusion region are formed in the silicon substrate, outside of the first side wall dielectric film and outside of the second side wall dielectric film, respectively.

12. The method according to claim 8, further comprising the step of:
forming, after the step of forming the first side wall oxide film and the second side wall oxide film and before the step of forming the first side wall dielectric film and the second side wall dielectric film, a third side wall oxide film on the first side wall oxide film in such a manner that the third side wall oxide film continuously extends to cover a part of a surface of the silicon substrate, and also forming a fourth side wall oxide film on the second side wall oxide film in such a manner that the fourth side wall oxide film continuously extends to cover a part of the surface of the silicon substrate, wherein:
the step of forming the first side wall dielectric film and the second side wall dielectric film is performed in such a manner that the first side wall dielectric film covers the third side wall oxide film and the second side wall dielectric film covers the fourth side wall oxide film.

13. The method according to claim 8, wherein:
the polycrystal silicon material comprises polysilicon.

14. The method according to claim 8, wherein:
the polycrystal silicon material comprises SiGe polycrystal.

15. A method of manufacturing a semiconductor device, the method comprising the steps of:
forming a polysilicon gate electrode defined by a first side wall and a second side wall on a substrate via a gate dielectric film;
forming a first diffusion region in the substrate on the same side as the first side wall of the polysilicon gate electrode and a second diffusion region in the substrate on the same side as the second side wall of the polysilicon gate electrode;
forming a first side wall oxide film on the first side wall on a first side of the polysilicon gate electrode and a second side wall oxide film on the second side wall on a second side of the polysilicon gate electrode;
forming, on the first side wall oxide film, a first side wall dielectric film having a different etching resistance from that of the first side wall oxide film, and forming, on the second side wall oxide film, a second side wall dielectric film having a different etching resistance from that of the second side wall oxide film;
etching the first side wall oxide film and the second side wall oxide film, starting from top edges thereof, selectively and partially with respect to the first side wall dielectric film and the second side wall dielectric film, in such a manner as to expose a top part of the polysilicon gate electrode;
etching the exposed polysilicon gate electrode in such a manner as to form a first gap in the polysilicon gate electrode between the first side wall oxide film and the second side wall oxide film, wherein the first gap is in communication with a second gap formed between the first side wall dielectric film and the second side wall dielectric film;
filling the first gap and the second gap with a polycrystal silicon material to thereby form a gate electrode head extending between an inner wall of the first side wall dielectric film and an inner wall of the second side wall dielectric film; and
forming a silicide layer on the gate electrode head.

16. The method according to claim 15, further comprising the step of:
forming, after the step of forming the first side wall oxide film and the second side wall oxide film and before the step of forming the first side wall dielectric film and the second side wall dielectric film, a third side wall oxide film on the first side wall oxide film in such a manner that the third side wall oxide film continuously extends to cover a part of a surface of the silicon substrate, and also forming a fourth side wall oxide film on the second side wall oxide film in such a manner that the fourth side wall oxide film continuously extends to cover a part of the surface of the silicon substrate, wherein:
the step of forming the first side wall dielectric film and the second side wall dielectric film is performed in such a manner that the first side wall dielectric film covers the third side wall oxide film and the second side wall dielectric film covers the fourth side wall oxide film.

17. The method according to claim 15, wherein:
the polycrystal silicon material comprises polysilicon.

18. The method according to claim 15, wherein:
the polycrystal silicon material comprises SiGe polycrystal.
